(19) United States
(12) Patent Application Publication
(10) Pub. No.: US 2009/0191681 A1
(43) Pub. Date: Jul. 30, 2009

(54) NOR-TYPE FLASH MEMORY DEVICE WITH TWIN BIT CELL STRUCTURE AND METHOD OF FABRICATING THE SAME

(75) Inventors: Jae-Man YOON, Seoul (KR); Suk-kang SUNG, Seongnam-si (KR); Dong-Gun PARK, Seongnam-si (KR); Choong-Ho LEE, Seongnam-si (KR); Tae-Yong KIM, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/418,639

(22) Filed: Apr. 6, 2009

Related U.S. Application Data
(62) Division of application No. 11/311,367, filed on Dec. 20, 2005.

(30) Foreign Application Priority Data
Dec. 27, 2004 (KR) 10-2004-0112899

(51) Int. Cl. H01L 21/336

(52) U.S. Cl. 438/287; 257/E21.423

(57) ABSTRACT

A NOR-type flash memory device comprises a plurality twin-bit memory cells arranged so that pairs of adjacent memory cells share a source/drain region and groups of four adjacent memory cells are electrically connected to each other by a single bitline contact.

### CROSS-REFERENCE TO RELATED APPLICATION

This is a divisional of application Ser. No. 11/311,367 filed on Dec. 20, 2005, which is incorporated herein by reference in its entirety.

### BACKGROUND OF THE INVENTION

1. Field of the Invention

The present invention relates generally to a flash memory device and a method of fabricating the same. More particularly, the invention relates to a highly integrated NOR-type flash memory device having a twin bit cell structure and a method of fabricating the same.

A claim of priority is made to Korean Patent Application No. 10-2004-0112899, filed on Dec. 27, 2004, the disclosure of which is hereby incorporated by reference in its entirety.

2. Description of Related Art

Nonvolatile semiconductor memories can be found in a wide variety of digital electronic applications such as computers, cellular phones, digital audio players, and cameras, to name but a few. One of the main advantages of nonvolatile semiconductor memories is their ability to retain stored data even when power is cut off. Among the more popular forms of nonvolatile semiconductor memories is flash memory.

To improve the performance and storage capacity of nonvolatile semiconductor memories, researchers are constantly developing new techniques for reducing the size and density of individual memory cells.

One technique used to produce smaller memory cells is to replace the traditional silicon floating gate structure of a flash memory cell with a nitride trapping layer formed of a material such as silicon nitride. Replacing the floating gate structure in this way can significantly reduce the size of the memory cell's gate structure without seriously reducing the cell's performance or reliability. Flash memory cells using a nitride trapping layer instead of the traditional floating gate structure include silicon-oxide-nitride-oxide-silicon (SONOS) memory cells and metal-oxide-nitride-oxide-silicon (MONOS) memory cells. An additional benefit of SONOS memory cells over traditional flash memory cells is that fabrication processes are simplified by not having to form the traditional floating gate structure.

Another technique which can be used to increase the density of memory cells in a memory cell array is to form the memory cells using a twin bit structure. In the twin bit structure, a gate structure is formed with two isolated charge trapping regions in the nitride trapping layer and source and drain regions are formed on opposite sides of the gate structure. The twin bit structure is commonly used with SONOS or MONOS memory cells, and therefore SONOS or MONOS memory cells having the twin bit structure are referred to as “twin bit memory cells”. Various flash memory cells using the twin bit structure are disclosed, for example, in U.S. Pat. Nos. 6,531,350, 6,707,079 and 6,808,991.

Using twin bit memory cells can increase the density of a semiconductor memory array by two times compared with a memory array using traditional floating gates and cell structures.

A twin bit memory cell is typically programmed using channel hot electron injection (CHEI). In CHEI, charges are injected into the silicon nitride layer located in the gate structure of a cell transistor by applying a high voltage between a gate electrode of the gate structure and a first source/drain junction formed on a first side of the gate structure. In contrast, a read operation is performed on the twin bit memory cell by applying a voltage between the gate electrode and a second source/drain junction formed on a second side of the gate structure. Data is erased from the SONOS memory cell by applying a high voltage to the drain junction, and connecting the gate electrode and a substrate of the memory cell to ground to remove the electrons from the silicon nitride layer. The electrons pass from the silicon nitride layer to the drain junction through an overlapping portion of the gate structure and the drain junction according to a phenomenon called band-to-band tunneling (BtBT).

A twin-bit memory cell typically stores two bits of data. This is generally accomplished by performing CHEI through a drain side of a cell transistor, where the cell transistor has a threshold voltage (Vth) that depends on the source resistance of the transistor.

Conventional NOR flash memory devices including twin bit memory cells typically employ a buried bitline structure (See, for example, U.S. Pat. No. 6,720,629). In a buried bitline structure, bitlines are generally formed under device isolation regions or they are formed using a simple PN junction. Also, in devices employing the buried bitline structure, a bitline of each transistor is formed in the same direction as a device isolation region below a corresponding wordline, and a source/drain region of the transistor is formed by a contact between the bitline and each memory cell. Unfortunately, the buried bitline structure can cause devices to malfunction due to punch-through of the transistor when the devices are scaled down.

### SUMMARY OF THE INVENTION

According to one embodiment of the invention, a NOR-type flash memory device comprises a plurality of active regions extending linearly in a first direction and formed on a substrate, a plurality of wordlines extending linearly in a second direction, a plurality of bitlines formed in the first direction, a plurality of memory cells formed on the active regions, each of the memory cells being defined by the intersection of one of the wordlines and one of the bitlines, and a plurality of source/drain regions formed in the active regions, each of the source/drain regions being shared by two adjacent memory cells. Each of the source/drain regions is electrically connected to a corresponding bitline via a bitline contact, and the bitline contact is connected to four adjacent memory cells.

According to another embodiment of the invention, a method of fabricating a NOR-type flash memory device comprises defining a plurality of active regions extending linearly in a first direction on a substrate, forming a dielectric layer on the active regions, forming a plurality of wordlines extending linearly in a second direction perpendicular to the first direction, forming a plurality of source/drain regions between the wordlines in the active regions, forming a first insulating interlayer having a plurality of contact holes on the wordlines to expose two of the plurality of source/drain regions, forming a plurality of conductive contact plugs filling the contact holes to electrically connect the two source/drain regions, and forming a plurality of bitlines, each electrically connected to one of the contact plugs via a single bitline contact.

### BRIEF DESCRIPTION OF THE DRAWINGS

The invention is described below in relation to several embodiments illustrated in the accompanying drawings. Throughout the drawings like reference numbers indicate like exemplary elements, components, or steps. In the drawings:

FIG. 1 is a circuit diagram of a memory cell array in a NOR-type flash memory device according to one embodiment of the present invention;

FIG. 2 illustrates a layout of a NOR-type flash memory device according to one embodiment of the present invention;

FIG. 3 illustrates a layout of a NOR-type flash memory device according to another embodiment of the present invention;

FIGS. 4A, 5A, . . . , and 9A are plan views showing a layout of primary parts in a process sequence to illustrate a method of fabricating a NOR-type flash memory device according to the first embodiment of the present invention;

FIGS. 4B, 5B, . . . , and 9B are cross-sectional views taken along a line X1-X1′ in FIGS. 4A, 5A, . . . , and 9A, respectively;

FIGS. 4C, 5C, . . . , and 9C are cross-sectional views taken along a line X2-X2′ in FIGS. 4A, 5A, . . . , and 9A, respectively;

FIGS. 4D, 5D, . . . , and 9D are cross-sectional views taken along a line Y1-Y1′ in FIGS. 4A, 5A, . . . , and 9A, respectively; and

FIG. 10 is a cross-sectional view illustrating a method of fabricating the NOR-type flash memory device according to another embodiment of the present invention.

### DESCRIPTION OF EXEMPLARY EMBODIMENTS

Exemplary embodiments of the invention are described below with reference to the corresponding drawings. These embodiments are presented as teaching examples. The actual scope of the invention is defined by the claims that follow.

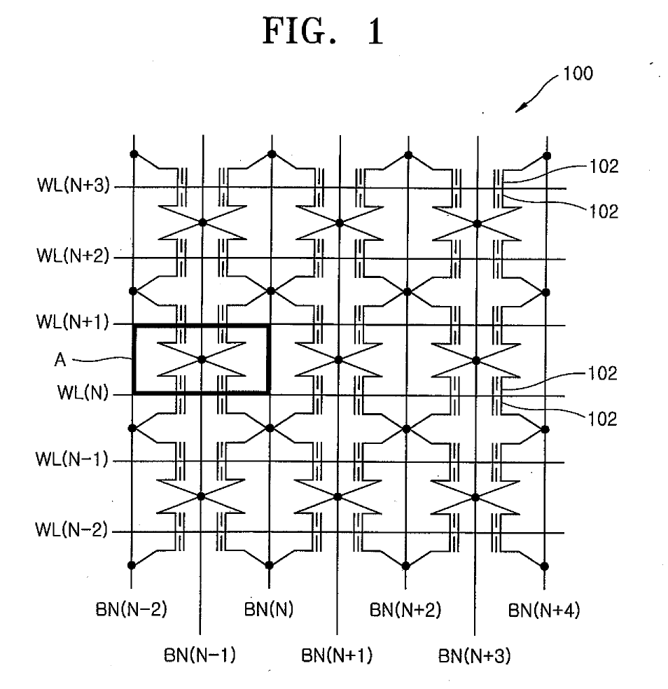

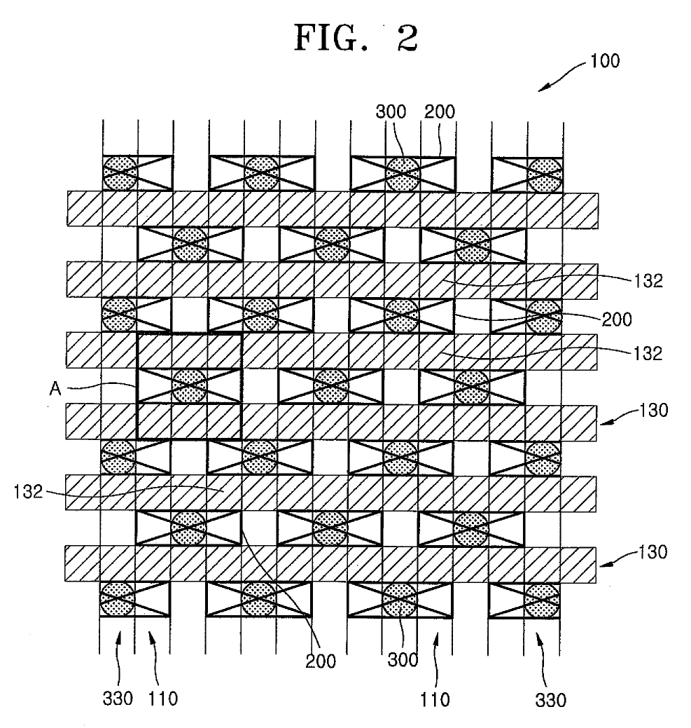

FIG. 1 is a schematic circuit diagram of a memory cell array 100 in a NOR-type flash memory device according to an embodiment of the present invention, and FIG. 2 illustrates a layout of the NOR-type flash memory device.

Referring to FIGS. 1 and 2, memory cell array 100 comprises a plurality of memory cells, each comprising a cell transistor 102. The memory cells are arranged in a matrix comprising several rows and columns, wherein the columns extend in a first direction and the rows extend in a second direction perpendicular to the first direction.

In memory cell array 100, a plurality of active regions 110 extend linearly in the first direction, and a plurality of wordlines 130 extend linearly in the second direction. In addition, a plurality of bitlines 330 extends linearly in the first direction over wordlines 130. Each intersection between wordlines 130 and bitlines 330 defines a memory cell in memory cell array 100.

Respective cell transistors 102 are formed to share a source/drain region in the first direction. One source/drain region shared by two adjacent cell transistors 102 in the first direction is coupled to another adjacent source/drain region in the row direction via a source/drain contact 200. Each source/drain contact 200 is coupled to a corresponding one of bitlines 330 by a bitline contact 300. In addition, each source/drain region in memory cell 100 may be electrically connected to a corresponding one of bitlines 330 via a bitline contact 300. As a result, memory cell array 100 comprises groups of four adjacent memory cells coupled to respective bitline contacts 300. A group of four adjacent memory cells connected to the same bitline contact 300 is indicated, for example, by a reference symbol “A” in FIGS. 1 and 2.

Each of the memory cells in the NOR-type flash memory device illustrated in FIG. 2 is formed by interposing a dielectric layer between one of active regions 110 and a corresponding gate 132, and forming an electron trapping layer within the dielectric layer. For example, the memory cell may be a SONOS memory cell.

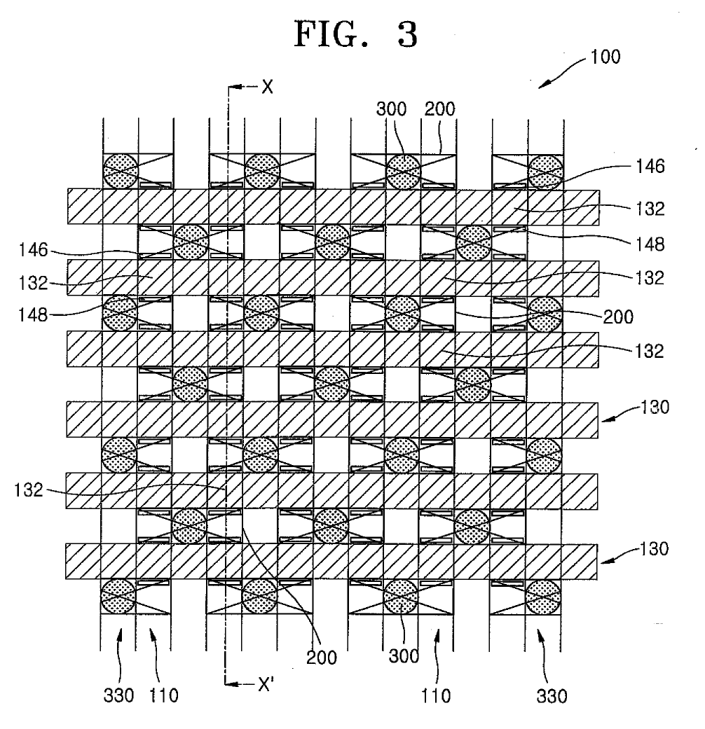

FIG. 3 shows a layout similar to the layout shown in FIG. 2. However, in the layout shown in FIG. 3, each memory cell is a split gate type memory cell.

In FIG. 3, each memory cell comprises first and second sidewall gates 146 and 148 formed on respective sidewalls of a gate 132. Each gate 132 is composed of a part of a wordline 130 and sidewall gates 146 and 148 are insulated from gate 132.

Because FIG. 3 and FIG. 2 contain many like elements, additional description of the like elements is omitted to avoid redundancy.

Each of the memory cells in FIGS. 1 through 3 is a twin bit cell. The feature size of each cell transistor 102 is determined by the dimensions and spacing of wordlines 130 and bitlines 330. Assuming that wordlines 130 and bitlines 330 both have a pitch of 2F, where “F” represents a feature size, e.g., the width of each bitline 330 or wordline 130, then each memory cell occupies an area of 4F². Therefore, because each memory cell stores 2 bits, the twin bit 4F² NOR-type flash memory stores 1 bit per 2F².

In addition, by forming NOR-type flash memory device 100 with bitlines 330 over wordlines 130 and with each bitline contact 300 shared by four cell transistors 102, device malfunctions caused by punch-through are also avoided. Punch through is avoided because adjacent bitlines are sufficiently insulated from each other. As a result, NOR flash memory device 100 can be more efficiently scaled than conventional memory devices.

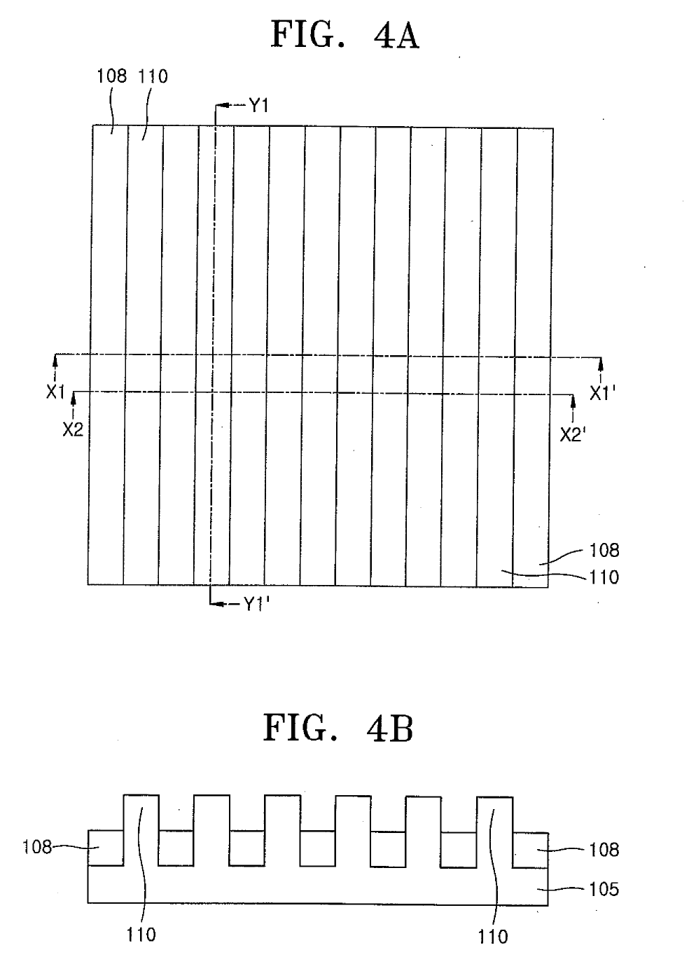

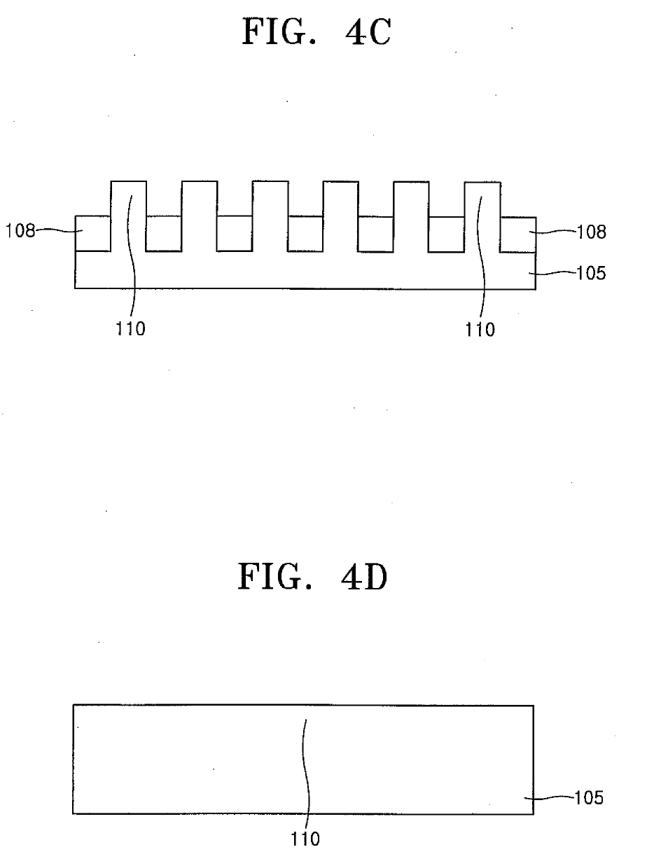

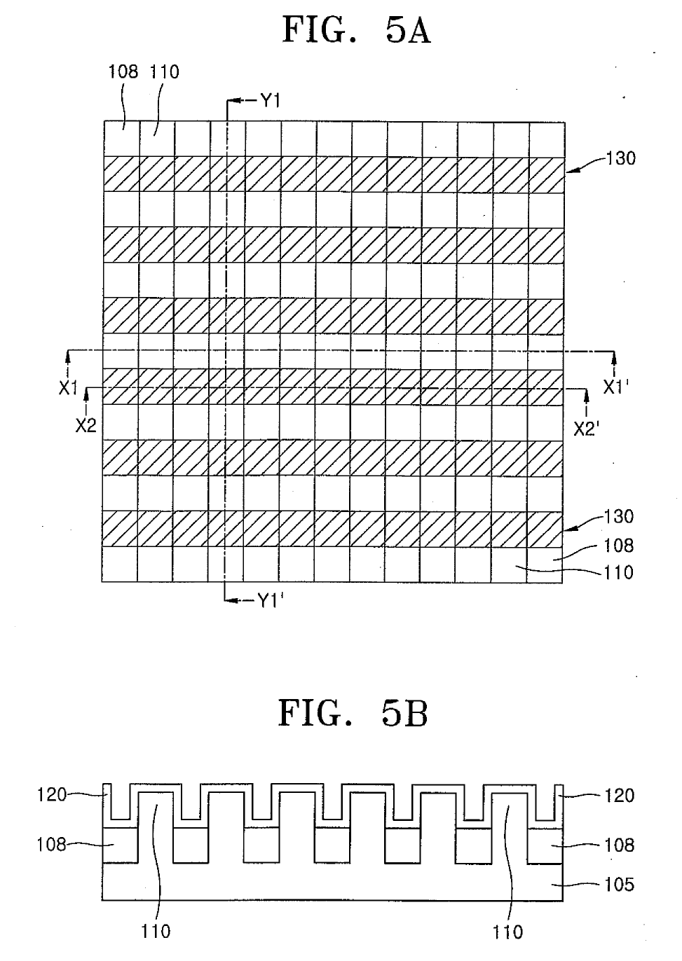

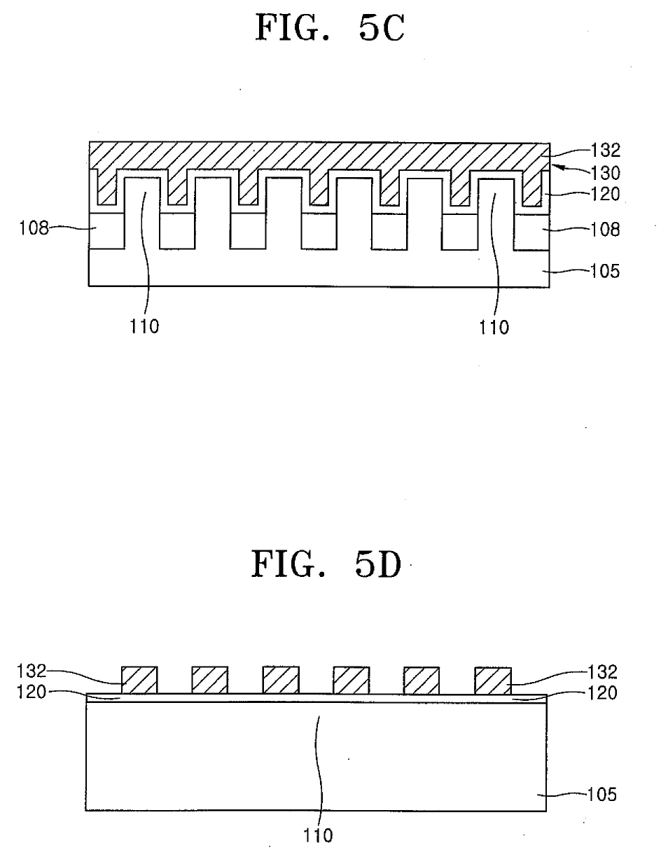

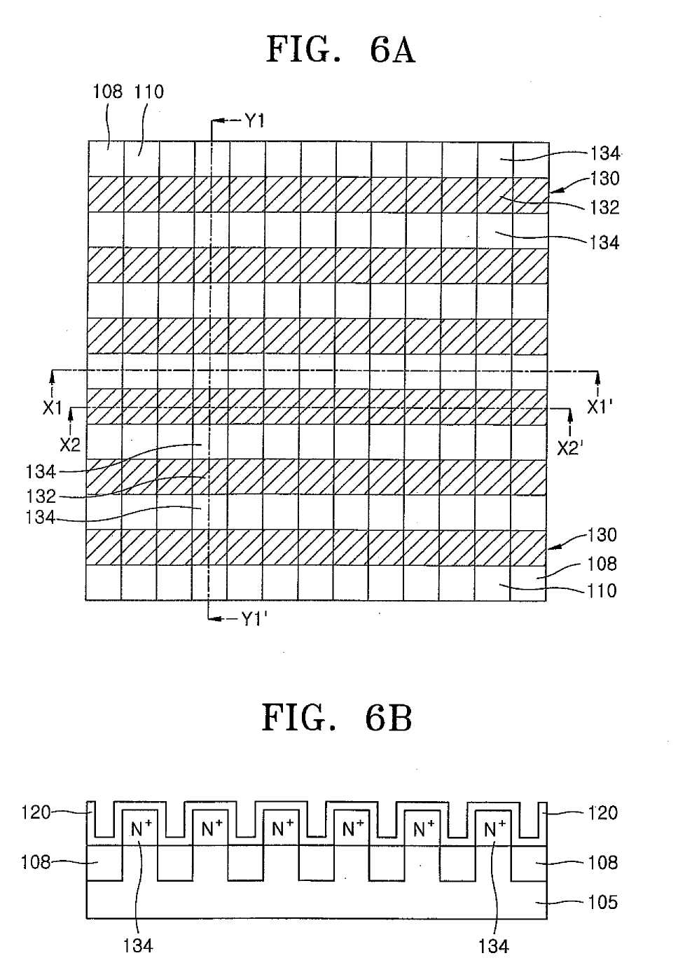

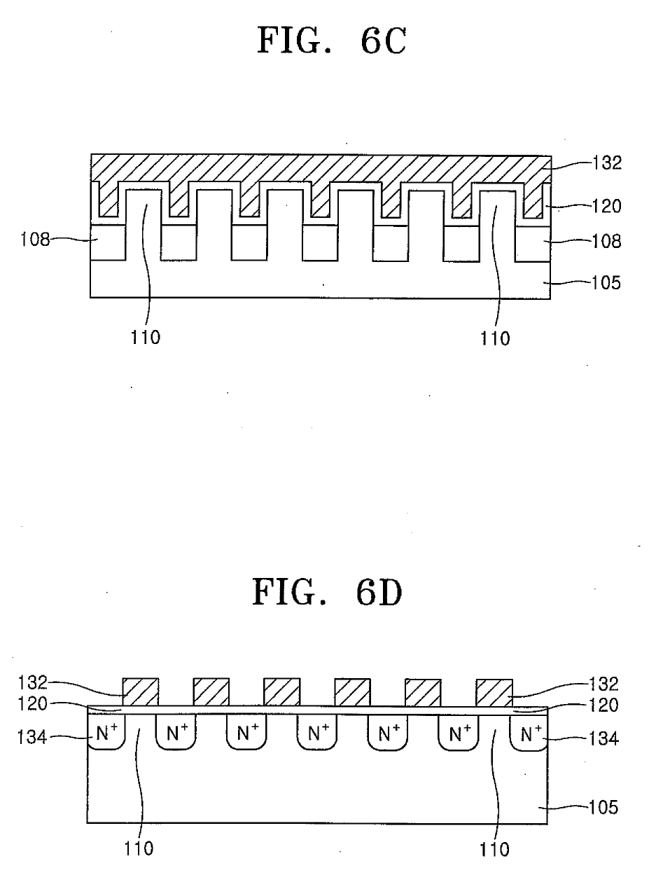

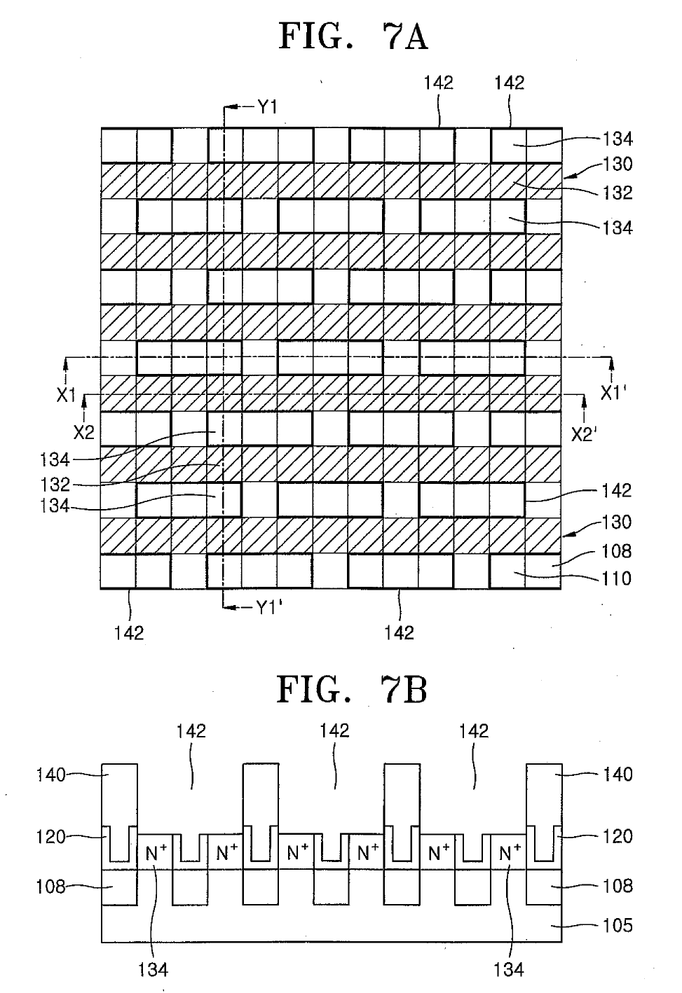

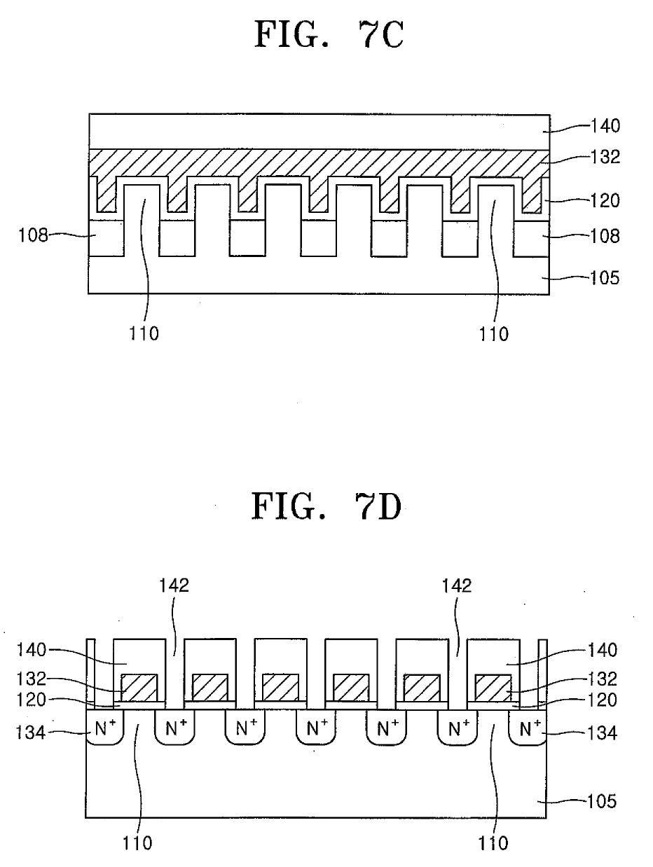

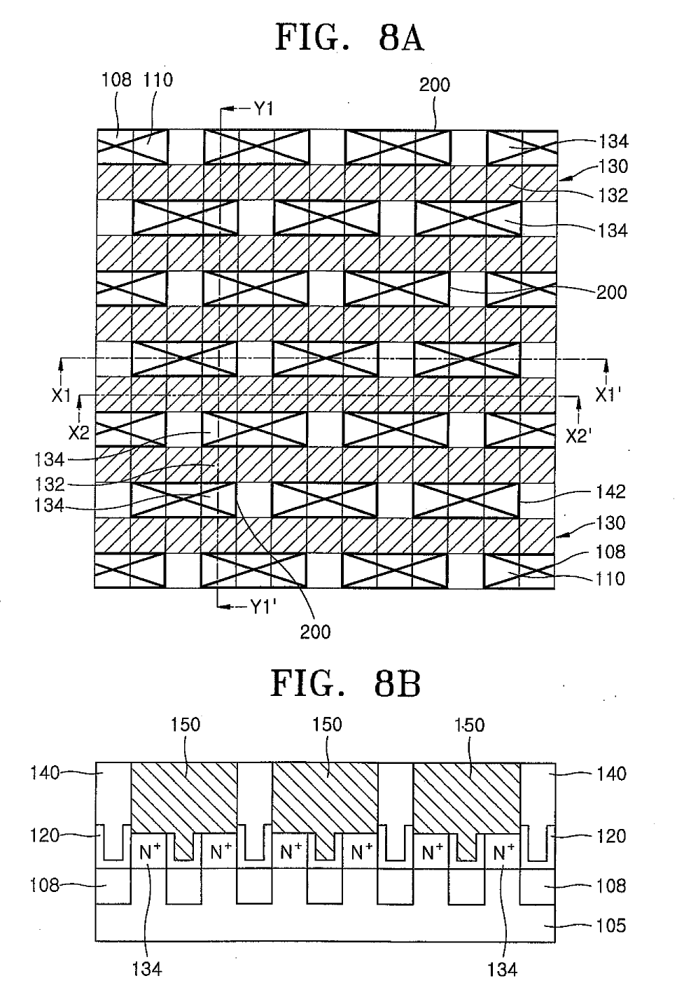

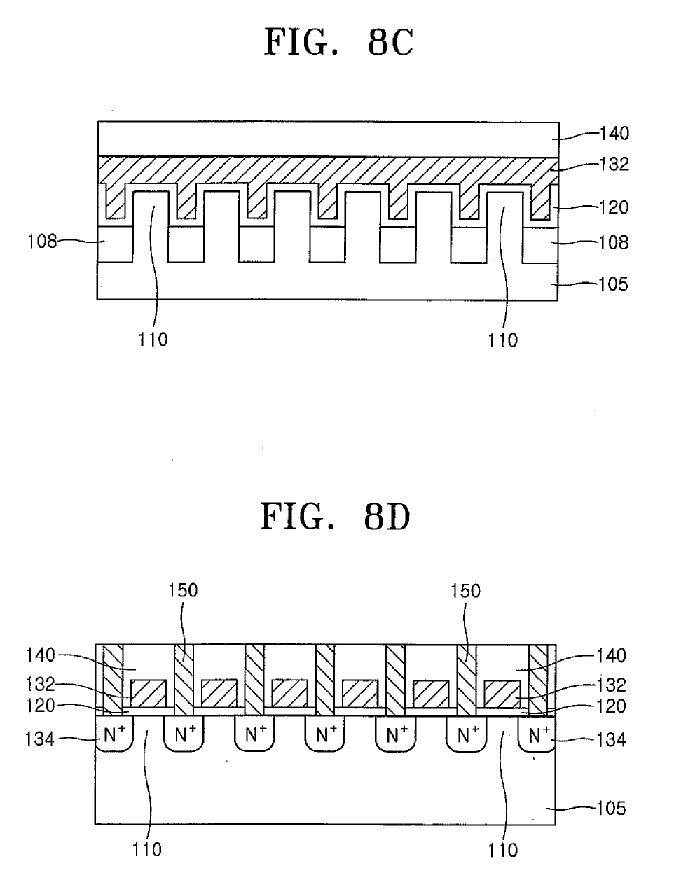

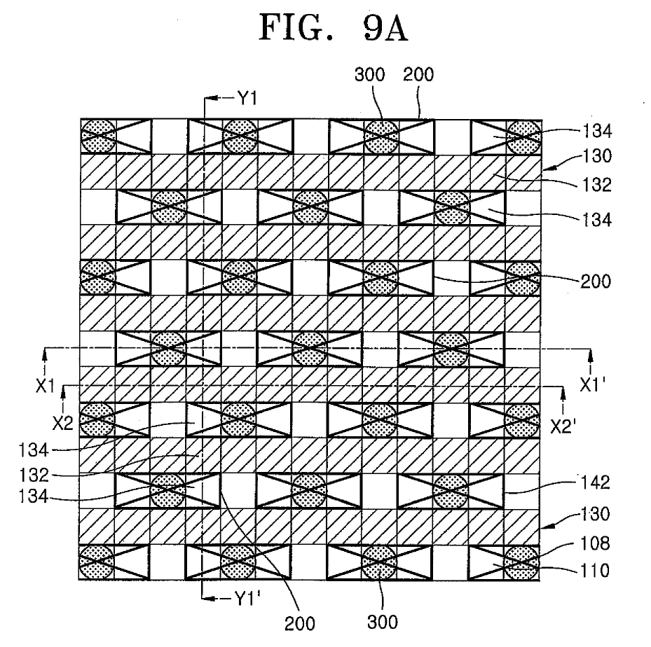

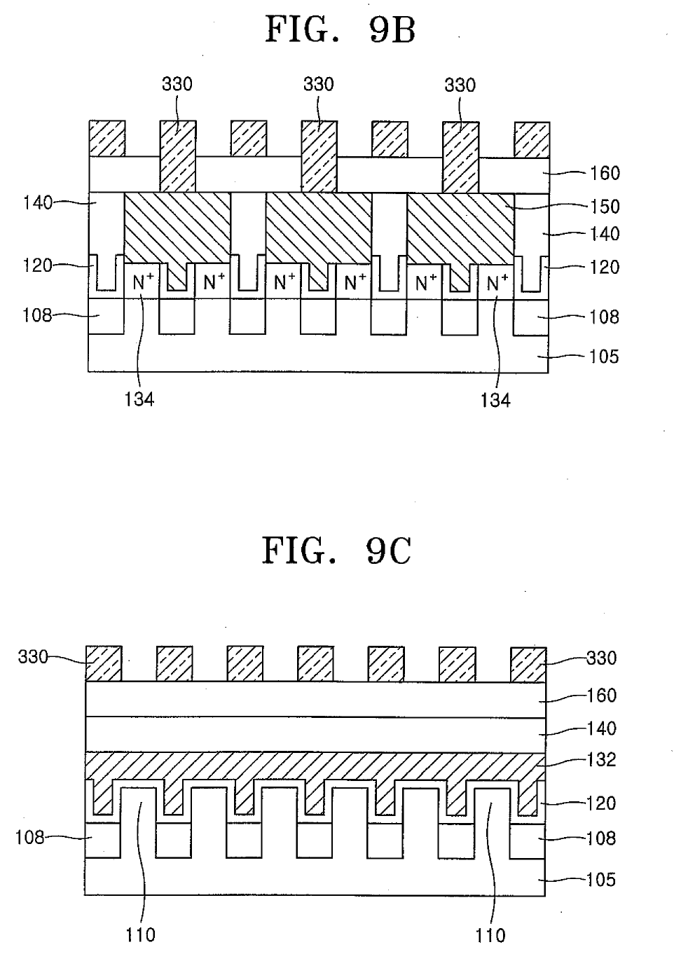

FIGS. 4A, 5A, . . . , and 9A are plan views illustrating a method of fabricating a NOR-type flash memory device according to an embodiment of the present invention. FIGS. 4B, 5B, . . . , and 9B are cross-sectional views taken along a line X1-X1′ in FIGS. 4A, 5A, . . . , and 9A, respectively. FIGS. 4C, 5C, . . . , and 9C are cross-sectional views taken along a line X2-X2′ of FIGS. 4A, 5A, . . . , and 9A, respectively. FIGS. 4D, 5D, . . . , and 9D are cross-sectional views taken along a line Y1-Y1′ of FIGS. 4A, 5A, . . . , and 9A, respectively.

Referring to FIGS. 4A, 4B, 4C, and 4D, a semiconductor substrate 105, such as a silicon substrate, is partially etched to form pin-shaped mesa-type active regions 110. An insulating material is deposited on the semiconductor substrate 105 having the mesa-type active regions 110 and is selectively partially removed to form device isolation regions, which are formed of shallow trench isolation (STI) regions 108 partially filling trenches between active regions 110. STI regions 108 extend linearly in a repeated pattern on semiconductor substrate 105. Active regions 110 defined by STI regions 108 extend linearly in the first direction as defined in FIG. 2. Although the device isolation regions in this embodiment comprise STI regions 108, other materials could also be used to form the device isolation regions. For example, the device isolation regions could be formed by local oxidation of silicon (LOCOS) regions.

Referring to FIGS. 5A, 5B, 5C and 5D, a dielectric layer 120 is formed on active regions 110. Dielectric layer 120 is typically formed by sequentially stacking a plurality of different dielectric layers to create a trapping layer within dielectric layer 120. For example, dielectric layer 120 typically comprises a first silicon oxide layer, a silicon nitride layer stacked on the first silicon oxide layer, and a second silicon oxide layer stacked on the silicon nitride layer. Alternatively, dielectric layer 120 may comprise an aluminum oxide layer, a silicon nitride layer stacked on the aluminum oxide layer, and a silicon oxide layer stacked on the silicon nitride layer. As another alternative, dielectric layer 120 could also comprise a first silicon oxide layer, a hafnium oxide layer stacked on the first silicon oxide layer, and a second silicon oxide layer stacked on the hafnium oxide layer.

A conductive layer, such as a doped polysilicon or metal layer, is formed on dielectric layer 120 and is patterned to form a plurality of wordlines 130 extending perpendicular to active regions 110 on dielectric layer 120. Wordlines 130 are formed to simultaneously cover a top surface and sidewalls of active regions 110. Wordlines 130 constitute gates 132 of the respective memory cells.

Referring to FIGS. 6A, 6B, 6C and 6D, impurity ions are injected between wordlines 130 in active region 110 to form a plurality of source/drain regions 134. Source/drain regions 134 are typically formed of N+ type impurity regions, as illustrated in FIG. 6D.

Referring to FIGS. 7A, 7B, 7C and 7D, a first insulating interlayer is formed to cover wordlines 130 and source/drain regions 134 and is patterned to form first insulating interlayer patterns 140, which have a plurality of source/drain contact holes 142 formed therein to simultaneously expose adjacent source/drain regions 134.

Referring to FIGS. 8A, 8B, 8C and 8D, a plurality of conductive contact plugs 150 are formed to fill source/drain contact holes 142, such that conductive contact plugs 150 come in contact with adjacent source/drain regions 134 in source/drain contact holes 142. In order to form contact plugs 150, a conductive material, such as a doped polysilicon or metal material, is deposited on first insulating interlayer patterns 140 and is subject to node isolation using an etch back process or chemical mechanical polishing (CMP). Contact plugs 150 constitute source/drain contacts 200 as shown in FIG. 8A.

Referring to FIGS. 9A, 9B, 9C and 9D, a second insulating interlayer pattern 160 is formed on contact plugs 150 to have contact holes exposing parts of contact plugs 150. A conductive layer, such as a doped polysilicon or metal layer, is then formed on second insulating interlayer pattern 160 and is patterned to form bitlines 330. Bitlines 330 are formed to be electrically connected to contact plugs 150 via bitline contacts 300 (see FIG. 9A).

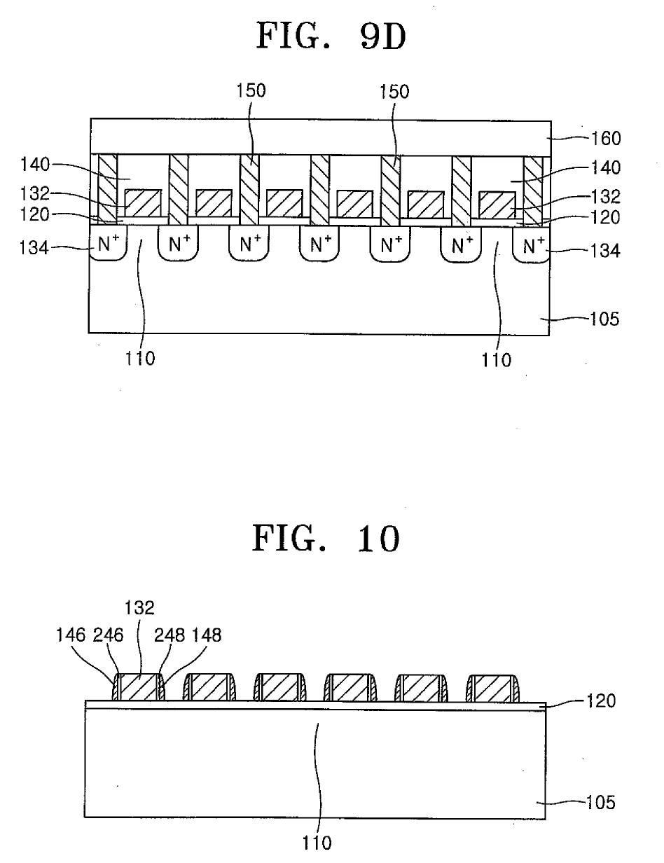

FIG. 10 is a cross-sectional view illustrating a method of fabricating a NOR-type flash memory device according to another embodiment of the present invention.

Referring to FIG. 10, the NOR-type flash memory device comprises split gate type memory cells as shown in FIG. 3. Indeed, FIG. 10 is a cross-sectional view taken along the line X-X′ in FIG. 3.

Referring to FIGS. 3 and 10, gates 132 and wordlines 130 are formed by the method as described with reference to FIGS. 4A through 4D and FIGS. 5A through 5D. Gates 132 are then coated with sequential thin dielectric and conductive layers. The dielectric and conductive layers are then etched back until top surfaces of gates 132 are exposed, thus removing unnecessary parts. A first sidewall gate 146 and a second sidewall gate 148 are formed to cover both sidewalls of gates 132. Finally, a dielectric layer 246 is interposed between gate 132 and first sidewall gate 146, and a dielectric layer 248 is interposed between gate 132 and second sidewall gate 148.

Thereafter, process described in relation to FIGS. 6A through 6D in and subsequent processes are performed.

Although the methods described above involve cell transistors formed on pin-shaped active regions, the cell transistors could be formed using other types of active regions. For example, a cell transistor could be formed on an active region comprising a one-dimensional plane defined by STI device isolation.

As described above, in a NOR-type flash memory device according to various embodiments of the present invention, four memory cells share a single bitline contact. In addition, the NOR-type flash memory device comprises a memory cell array including twin-bit cells, each storing 2-bits. Each of the twin-bit memory cells occupies an area of 4F², hence the NOR-type flash memory cell stores one bit per 2F².

In the NOR-type flash memory device described above, bitlines are formed over wordlines and one bitline contact is shared by four cell transistors. This prevents device malfunctions caused by punch-through, and facilitates insulation between adjacent bitlines, which is highly advantageous for scaling down the device.

The foregoing preferred embodiments are teaching examples. Those of ordinary skill in the art will understand that various changes in form and details may be made to the exemplary embodiments without departing from the scope of the present invention as defined by the claims that follow.

What is claimed is:

1. A method of fabricating a NOR-type flash memory device, the method comprising:
defining a plurality of active regions extending linearly in a first direction on a substrate;
forming a dielectric layer on the active regions;
forming a plurality of wordlines extending linearly in a second direction perpendicular to the first direction;
forming a plurality of source/drain regions between the wordlines in the active regions;
forming a first insulating interlayer having a plurality of contact holes on the wordlines to expose two of the plurality of source/drain regions;
forming a plurality of conductive contact plugs filling the contact holes to electrically connect the two source/drain regions; and,
forming a plurality of bitlines, each electrically connected to one of the contact plugs via a single bitline contact.

2. The method of claim 1, further comprising:
linearly forming a plurality of shallow trench isolation (STI) regions on the substrate to define the active regions.

3. The method of claim 1, wherein defining the active regions comprises:
forming a plurality of pin-shaped mesa-type active regions by partially etching the substrate; and,
forming device isolation layers between the respective mesa-type active regions.

4. The method of claim 1, wherein the dielectric layer is formed by sequentially stacking a plurality of different types of dielectric layers including a trapping layer.

5. The method of claim 4, wherein the dielectric layer comprises:
a first silicon oxide layer, a silicon nitride layer formed on the first silicon oxide layer, and a second silicon oxide layer formed on the silicon nitride layer.

6. The method of claim 4, wherein the dielectric layer comprises:
an aluminum oxide layer, a silicon nitride layer formed on the aluminum oxide layer, and a silicon oxide layer formed on the silicon nitride layer.

7. The method of claim 4, wherein the dielectric layer comprises:
a silicon oxide layer, a hafnium oxide layer formed on the silicon oxide layer, and a silicon oxide layer formed on the hafnium oxide layer.

8. The method of claim 5, wherein the wordlines are formed to simultaneously cover a top surface and sidewalls of the mesa-type active regions.

9. The method of claim 1, wherein the wordlines are formed to cover a top surface of the active regions.

10. The method of claim 1, wherein the wordlines are formed to extend linearly.

11. The method of claim 1, further comprising:
after forming the wordlines and before forming the source/drain regions,
forming a first sidewall gate on the active region to cover a first sidewall of the wordline; and
forming a second sidewall gate on the active region to cover a second sidewall of the wordline.

12. The method of claim 1, wherein the plurality of active regions comprises:
a first active region, and a second active region formed adjacent to the first active region; and,
wherein the two exposed source/drain regions comprise a first source/drain region formed in the first active region and a second source/drain region formed in the second active region.

13. The method of claim 1, wherein the bitlines extend linearly in the first direction.

14. The method of claim 1, wherein the bitlines are formed to be connected with respective contact plugs via bitline contacts.
